(19) United States
(12) Patent Application Publication
(10) Pub. No.: US 2025/0238318 A1
(43) Pub. Date: Jul. 24, 2025

(54) DOUBLE DEVICE DATA CORRECTION IN MEMORY DEVICES USING ENLARGED REED-SOLOMON CODEWORDS

(71) Applicant: Micron Technology, Inc., Boise, ID (US)

(72) Inventors: Marco SFORZIN, Cernusco Sul Naviglio (IT); Nicola DEL GATTO, Cassina De' Pecchi (IT)

(21) Appl. No.: 18/985,901

(22) Filed: Dec. 18, 2024

Related U.S. Application Data
(60) Provisional application No. 63/622,495, filed on Jan. 18, 2024.

(51) Int. Cl. G06F 11/10

(52) U.S. Cl. CPC G06F 11/1068; G06F 11/1048

(57) ABSTRACT

In some implementations, a memory device may associate a first memory stripe with a second memory stripe. The memory device may receive a first codeword associated with the first memory stripe. The memory device may identify, using the first codeword, a first error in a first set of data bits that are associated with the first memory stripe. The memory device may correct the first error using the first codeword. The memory device may receive a second codeword associated with the first memory stripe and the second memory stripe. The memory device may identify, using the second codeword, a second error in a second set of data bits that are associated with the first memory stripe and the second memory stripe. The memory device may correct the second error using the second codeword.

### CROSS-REFERENCE TO RELATED APPLICATION

This patent application claims priority to U.S. Provisional Patent Application No. 63/622,495, filed on Jan. 18, 2024, entitled “DOUBLE DEVICE DATA CORRECTION IN MEMORY DEVICES USING ENLARGED REED-SOLOMON CODEWORDS,” and assigned to the assignee hereof. The disclosure of the prior application is considered part of and is incorporated by reference into this patent application.

### TECHNICAL FIELD

The present disclosure generally relates to memory devices, memory device operations, and, for example, to double device data correction in memory devices using enlarged Reed-Solomon codewords.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, an electronic device may write to, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), holographic RAM (HRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source. In some examples, a memory device may be associated with a compute express link (CXL). For example, the memory device may be a CXL compliant memory device and/or may include a CXL interface.

### BRIEF DESCRIPTION OF THE DRAWINGS

FIG. 1 is a diagram illustrating an example system capable of double device data correction in memory devices using enlarged Reed-Solomon (RS) codewords.

FIGS. 2A-2C are diagrams of examples associated with error correction codes.

FIGS. 3A-3D are diagrams of an example of double device data correction (DDDC) in memory devices using enlarged RS codewords.

FIG. 4 is a flowchart of an example method associated with DDDC in memory devices using enlarged RS codewords.

### DETAILED DESCRIPTION

Memory systems and/or devices may utilize an error correction code (ECC) to identify and/or correct errors in data accessed from memory. For example, data may be striped across multiple memory dies (sometimes referred to herein as a memory stripe), with the multiple dies used to store data bits and/or parity bits. For example, a memory stripe may be associated with ten dies (e.g., ten dynamic random-access memory (DRAM) dies), with eight dies used to store data bits and with two dies used to store parity bits. In some examples, the parity bits may store information that can be used in connection with an ECC to correct data, such as in an event in which an entire die fails (sometimes referred to as a chipkill protection). For example, in the event that an entire die of a DRAM stack fails, the parity bits stored may be encoded in such a way that the parity bits may be used to recover data that was stored on the failed die.

In some examples, an ECC may be associated with a Reed-Solomon (RS) code and/or a memory stripe may be associated with an RS chipkill protection scheme. For example, a memory system and/or device may utilize an 8-bit RS code, a 16-bit RS code, or a similar RS code to correct a number of bits corresponding to one failed die in a memory stripe, thereby providing chipkill protection in an event in which an entire die of the memory stripe fails. However, ECC procedures implementing RS codes may not be effective if more than one data die of a memory stripe fails and/or contains errors. Accordingly, if a first chipkill event occurs in connection with a memory stripe, an RS code may be capable of correcting the error and/or retrieving the lost data. However, if a second or subsequent chipkill event occurs in connection with the memory stripe, the RS code may not be capable of correcting the error and/or retrieving the lost data, resulting in an uncorrectable error. This may result in unreliable memory systems, unrecoverable host data, read/write errors, and high power, computing, and storage consumption for moving host data, rewriting host data, and/or recovering host data.

Some implementations described herein enable double device data correction (DDDC) (e.g., correction of errors associated with two or more failed dies of a memory stripe) for certain memory systems, such as memory systems employing RS-based error correction schemes. In some implementations, a memory system may associate multiple memory stripes (e.g., two memory stripes) with each other, with each memory stripe including respective data storage elements (e.g., data dies) and respective error correction elements (e.g., parity dies). In some implementations, a memory controller, an encoder/decoder component, and/or another component of a memory system may be capable of encoding and/or decoding an enlarged RS codeword after a first die failure, such as for a purpose of correcting errors associated with a second or subsequent die failure. For example, in some implementations, a memory system may associate two memory stripes with one another and/or pair original RS codewords. An original (e.g., un-enlarged) RS codeword may be used to correct a first die failure. Moreover, following a first die failure, recovered data may be written to an error correction element (e.g., a parity die) of a first memory stripe, and the error correction elements of a second memory stripe may be used to store error correction bits for an enlarged codeword associated with both the first memory stripe and the second memory stripe. In this way, if another data storage element (e.g., a data die) of the first memory stripe and/or the second memory stripe fails, the memory system may recover the lost data using the error correction bits stored in the error correction elements of the second memory stripe, thereby enabling DDDC at the memory system. This may result in increased reliability of the memory system, reduced data loss and/or read/write errors, and reduced power, computing, and storage consumption otherwise required to move host data, rewrite host data, and/or recover host data.

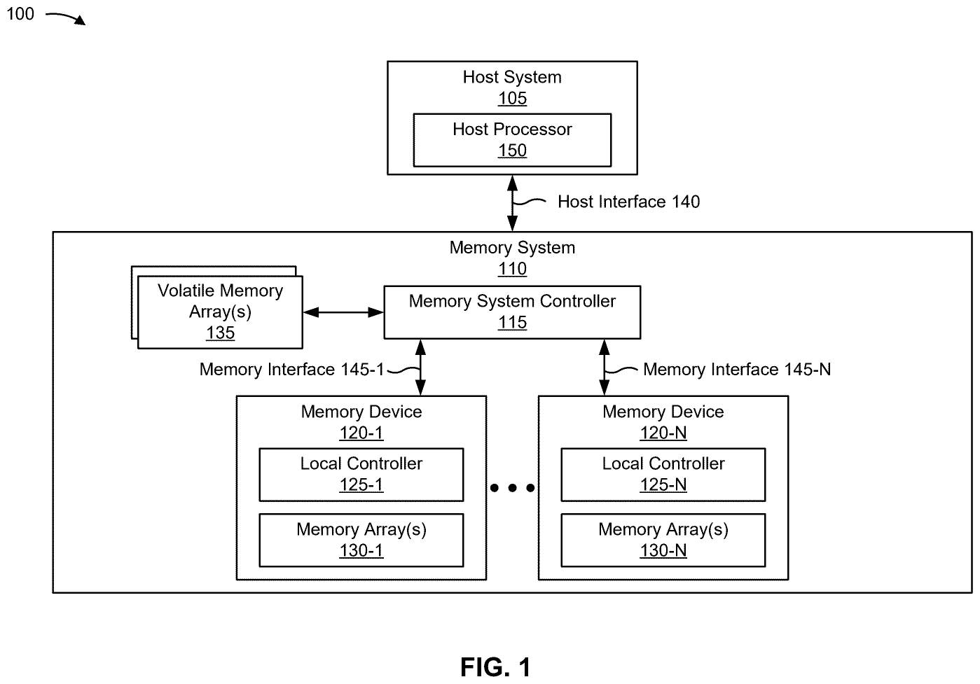

FIG. 1 is a diagram illustrating an example system 100 capable of double device data correction in memory devices using enlarged Reed-Solomon (RS) codewords. The system 100 may include one or more devices, apparatuses, and/or components for performing operations described herein. For example, the system 100 may include a host system 105 and a memory system 110. The memory system 110 may include a memory system controller 115 and one or more memory devices 120, shown as memory devices 120-1 through 120-N (where N≥1). A memory device may include a local controller 125 and one or more memory arrays 130. The host system 105 may communicate with the memory system 110 (e.g., the memory system controller 115 of the memory system 110) via a host interface 140. The memory system controller 115 and the memory devices 120 may communicate via respective memory interfaces 145, shown as memory interfaces 145-1 through 145-N (where N≥1).

The system 100 may be any electronic device configured to store data in memory. For example, the system 100 may be a computer, a mobile phone, a wired or wireless communication device, a network device, a server, a device in a data center, a device in a cloud computing environment, a vehicle (e.g., an automobile or an airplane), and/or an Internet of Things (IoT) device. The host system 105 may include a host processor 150. The host processor 150 may include one or more processors configured to execute instructions and store data in the memory system 110. For example, the host processor 150 may include a central processing unit (CPU), a graphics processing unit (GPU), a field-programmable gate array (FPGA), an application-specific integrated circuit (ASIC), and/or another type of processing component.

The memory system 110 may be any electronic device or apparatus configured to store data in memory. For example, the memory system 110 may be a hard drive, a solid-state drive (SSD), a flash memory system (e.g., a NAND flash memory system or a NOR flash memory system), a universal serial bus (USB) drive, a memory card (e.g., a secure digital (SD) card), a secondary storage device, a non-volatile memory express (NVMe) device, an embedded multimedia card (eMMC) device, a dual in-line memory module (DIMM), and/or a random-access memory (RAM) device, such as a dynamic RAM (DRAM) device or a static RAM (SRAM) device.

The memory system controller 115 may be any device configured to control operations of the memory system 110 and/or operations of the memory devices 120. For example, the memory system controller 115 may include control logic, a memory controller, a system controller, an ASIC, an FPGA, a processor, a microcontroller, and/or one or more processing components. In some implementations, the memory system controller 115 may communicate with the host system 105 and may instruct one or more memory devices 120 regarding memory operations to be performed by those one or more memory devices 120 based on one or more instructions from the host system 105. For example, the memory system controller 115 may provide instructions to a local controller 125 regarding memory operations to be performed by the local controller 125 in connection with a corresponding memory device 120.

A memory device 120 may include a local controller 125 and one or more memory arrays 130. In some implementations, a memory device 120 includes a single memory array 130. In some implementations, each memory device 120 of the memory system 110 may be implemented in a separate semiconductor package or on a separate die that includes a respective local controller 125 and a respective memory array 130 of that memory device 120. The memory system 110 may include multiple memory devices 120.

A local controller 125 may be any device configured to control memory operations of a memory device 120 within which the local controller 125 is included (e.g., and not to control memory operations of other memory devices 120). For example, the local controller 125 may include control logic, a memory controller, a system controller, an ASIC, an FPGA, a processor, a microcontroller, and/or one or more processing components. In some implementations, the local controller 125 may communicate with the memory system controller 115 and may control operations performed on a memory array 130 coupled with the local controller 125 based on one or more instructions from the memory system controller 115. As an example, the memory system controller 115 may be an SSD controller, and the local controller 125 may be a NAND controller.

A memory array 130 may include an array of memory cells configured to store data. For example, a memory array 130 may include a non-volatile memory array (e.g., a NAND memory array or a NOR memory array) or a volatile memory array (e.g., an SRAM array or a DRAM array). In some implementations, the memory system 110 may include one or more volatile memory arrays 135. A volatile memory array 135 may include an SRAM array and/or a DRAM array, among other examples. The one or more volatile memory arrays 135 may be included in the memory system controller 115, in one or more memory devices 120, and/or in both the memory system controller 115 and one or more memory devices 120. In some implementations, the memory system 110 may include both non-volatile memory capable of maintaining stored data after the memory system 110 is powered off and volatile memory (e.g., a volatile memory array 135) that requires power to maintain stored data and that loses stored data after the memory system 110 is powered off. For example, a volatile memory array 135 may cache data read from or to be written to non-volatile memory, and/or may cache instructions to be executed by a controller of the memory system 110.

The host interface 140 enables communication between the host system 105 (e.g., the host processor 150) and the memory system 110 (e.g., the memory system controller 115). The host interface 140 may include, for example, a Small Computer System Interface (SCSI), a Serial-Attached SCSI (SAS), a Serial Advanced Technology Attachment (SATA) interface, a Peripheral Component Interconnect Express (PCIe) interface, an NVMe interface, a USB interface, a Universal Flash Storage (UFS) interface, an eMMC interface, a double data rate (DDR) interface, and/or a DIMM interface.

The memory interface 145 enables communication between the memory system 110 and the memory device 120. The memory interface 145 may include a non-volatile memory interface (e.g., for communicating with non-volatile memory), such as a NAND interface or a NOR interface. Additionally, or alternatively, the memory interface 145 may include a volatile memory interface (e.g., for communicating with volatile memory), such as a DDR interface.

In some examples, the memory system 110 may be a compute express link (CXL) compliant memory system (sometimes referred to herein simply as a CXL memory system) and/or one or more of the memory devices 120 may be CXL compliant memory devices (sometimes referred to herein simply as a CXL memory device). CXL is a high-speed CPU-to-device and CPU-to-memory interconnect designed to accelerate next-generation performance. CXL technology maintains memory coherency between the CPU memory space and memory on attached devices, which allows resource sharing for higher performance, reduced software stack complexity, and lower overall system cost. CXL is designed to be an industry open standard interface for high-speed communications. CXL technology is built on the PCIe infrastructure, leveraging PCIe physical and electrical interfaces to provide an advanced protocol in areas such as input/output (I/O) protocol, memory protocol, and coherency interface.

In some examples, the memory system 110 may include a PCIe/CXL interface (e.g., the host interface 140 may be associated with a PCIe/CXL interface), which may be a physical interface configured to connect the CXL memory system and/or the CXL memory device to CXL compliant host devices. In such examples, the PCIe/CXL interface may comply with CXL standard specifications for physical connectivity, ensuring broad compatibility and ease of integration into existing systems using the CXL protocol. Additionally, or alternatively, a CXL memory system and/or a CXL memory device may be designed to efficiently interface with computing systems (e.g., the host system 105) by leveraging the CXL protocol. For example, a CXL memory system and/or a CXL memory device may be configured to utilize high-speed, low-latency interconnect capabilities of CXL, such as for a purpose of making the CXL memory system and/or the CXL memory device suitable for high-performance computing, data center applications, artificial intelligence (AI) applications, and/or similar applications.

A CXL memory system and/or a CXL memory device may include a CXL memory controller (e.g., memory system controller 115 and/or local controller 125), which may be configured to manage data flow between memory arrays (e.g., volatile memory arrays 135 and/or memory arrays 130) and a CXL interface (e.g., a PCIe/CXL interface, such as host interface 140). In some examples, the CXL memory controller may be configured to handle one or more CXL protocol layers, such as an I/O layer (e.g., a layer associated with a CXL.io protocol, which may be used for purposes such as device discovery, configuration, initialization, I/O virtualization, direct memory access (DMA) using non-coherent load-store semantics, and/or similar purposes); a cache coherency layer (e.g., a layer associated with a CXL.cache protocol, which may be used for purposes such as caching host memory using a modified, exclusive, shared, invalid (MESI) coherence protocol, or similar purposes); or a memory protocol layer (e.g., a layer associated with a CXL.memory (sometimes referred to as CXL.mem) protocol, which may enable a CXL memory device to expose host-managed device memory (HDM) to permit a host device to manage and access memory similar to a native DDR connected to the host); among other examples.

A CXL memory system and/or a CXL memory device may further include and/or be associated with one or more high-bandwidth memory modules (HBMMs) or similar memory arrays (e.g., volatile memory arrays 135 and/or memory arrays 130). For example, a CXL memory system and/or a CXL memory device may include multiple layers of DRAM (e.g., stacked and/or interconnected through advanced through-silicon via (TSV) technology) in order to maximize storage density and/or enhance data transfer speeds between memory layers. Additionally, or alternatively, a CXL memory system and/or a CXL memory device may include a power management unit, which may be configured to regulate power consumption associated with the CXL memory system and/or the CXL memory device and/or which may be configured to improve energy efficiency for the CXL memory system and/or the CXL memory device. Additionally, or alternatively, a CXL memory system and/or a CXL memory device may include additional components, such as one or more error correction code (ECC) engines, such as for a purpose of detecting and/or correcting data errors to ensure data integrity and/or improve the overall reliability of the CXL memory system and/or the CXL memory device.

Although the example memory system 110 described above includes a memory system controller 115, in some implementations, the memory system 110 does not include a memory system controller 115. For example, an external controller (e.g., included in the host system 105) and/or one or more local controllers 125 included in one or more corresponding memory devices 120 may perform the operations described herein as being performed by the memory system controller 115. Furthermore, as used herein, a “controller” may refer to the memory system controller 115, a local controller 125, or an external controller. In some implementations, a set of operations described herein as being performed by a controller may be performed by a single controller. For example, the entire set of operations may be performed by a single memory system controller 115, a single local controller 125, or a single external controller. Alternatively, a set of operations described herein as being performed by a controller may be performed by more than one controller. For example, a first subset of the operations may be performed by the memory system controller 115 and a second subset of the operations may be performed by a local controller 125. Furthermore, the term “memory apparatus” may refer to the memory system 110 or a memory device 120, depending on the context.

A controller (e.g., the memory system controller 115, a local controller 125, or an external controller) may control operations performed on memory (e.g., a memory array 130), such as by executing one or more instructions. For example, the memory system 110 and/or a memory device 120 may store one or more instructions in memory as firmware, and the controller may execute those one or more instructions. Additionally, or alternatively, the controller may receive one or more instructions from the host system 105 and/or from the memory system controller 115, and may execute those one or more instructions. In some implementations, a non-transitory computer-readable medium (e.g., volatile memory and/or non-volatile memory) may store a set of instructions (e.g., one or more instructions or code) for execution by the controller. The controller may execute the set of instructions to perform one or more operations or methods described herein. In some implementations, execution of the set of instructions, by the controller, causes the controller, the memory system 110, and/or a memory device 120 to perform one or more operations or methods described herein. In some implementations, hardwired circuitry is used instead of or in combination with the one or more instructions to perform one or more operations or methods described herein. Additionally, or alternatively, the controller may be configured to perform one or more operations or methods described herein. An instruction is sometimes called a “command.”

For example, the controller (e.g., the memory system controller 115, a local controller 125, or an external controller) may transmit signals to and/or receive signals from memory (e.g., one or more memory arrays 130) based on the one or more instructions, such as to transfer data to (e.g., write or program), to transfer data from (e.g., read), to erase, and/or to refresh all or a portion of the memory (e.g., one or more memory cells, pages, sub-blocks, blocks, or planes of the memory). Additionally, or alternatively, the controller may be configured to control access to the memory and/or to provide a translation layer between the host system 105 and the memory (e.g., for mapping logical addresses to physical addresses of a memory array 130). In some implementations, the controller may translate a host interface command (e.g., a command received from the host system 105) into a memory interface command (e.g., a command for performing an operation on a memory array 130).

In some implementations, one or more systems, devices, apparatuses, components, and/or controllers of FIG. 1 may be configured to associate a first memory stripe with a second memory stripe, wherein the first memory stripe is associated with a first set of data storage elements and a first set of error correction elements, and wherein the second memory stripe is associated with a second set of data storage elements and a second set of error correction elements; receive a first codeword associated with the first memory stripe, wherein the first codeword includes a first set of data bits associated with data stored at the first set of data storage elements and a first set of error correction bits associated with parity information stored at the first set of error correction elements; identify a first error in the first set of data bits using the first codeword; correct the first error using the first codeword; receive a second codeword associated with the first memory stripe and the second memory stripe, wherein the second codeword includes a second set of data bits associated with the data stored at the first set of data storage elements, data stored at the second set of data storage elements, and data stored at at least one error correction element, of the first set of error correction elements, and wherein the second codeword includes a second set of error correction bits associated with parity information stored at the second set of error correction elements; identify a second error in the second set of data bits; and correct the second error using the second codeword.

The number and arrangement of components shown in FIG. 1 are provided as an example. In practice, there may be additional components, fewer components, different components, or differently arranged components than those shown in FIG. 1. Furthermore, two or more components shown in FIG. 1 may be implemented within a single component, or a single component shown in FIG. 1 may be implemented as multiple, distributed components. Additionally, or alternatively, a set of components (e.g., one or more components) shown in FIG. 1 may perform one or more operations described as being performed by another set of components shown in FIG. 1.

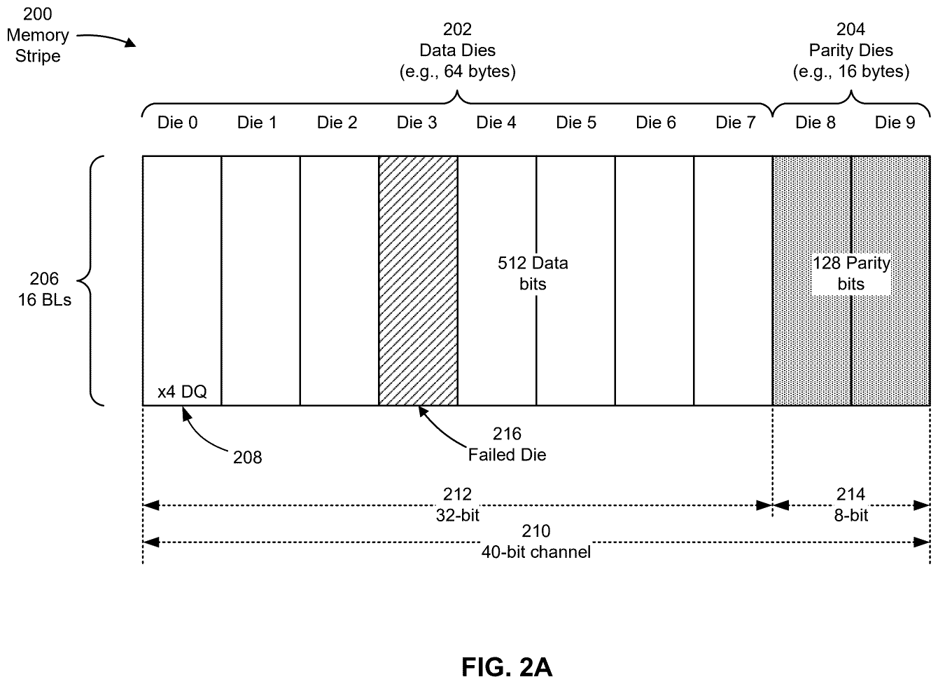

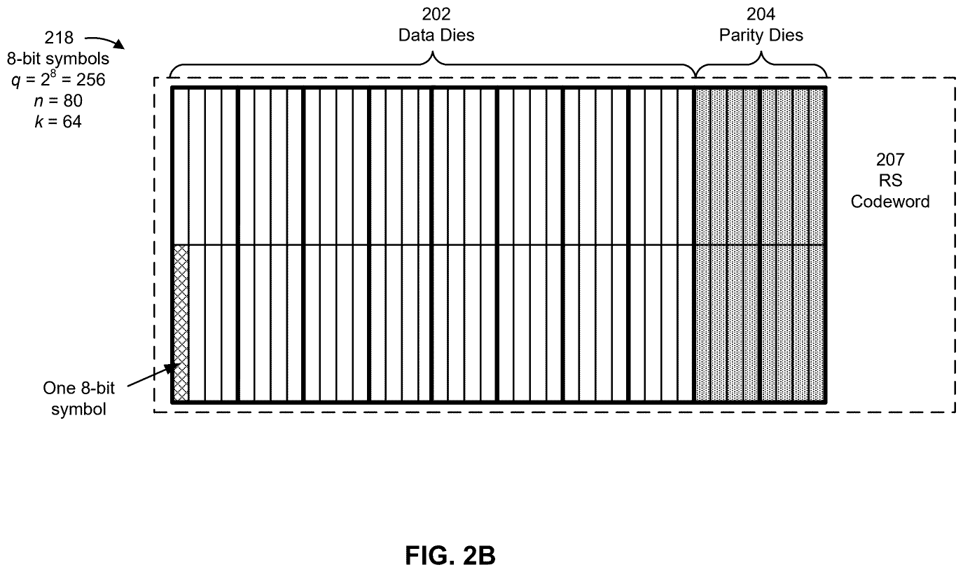

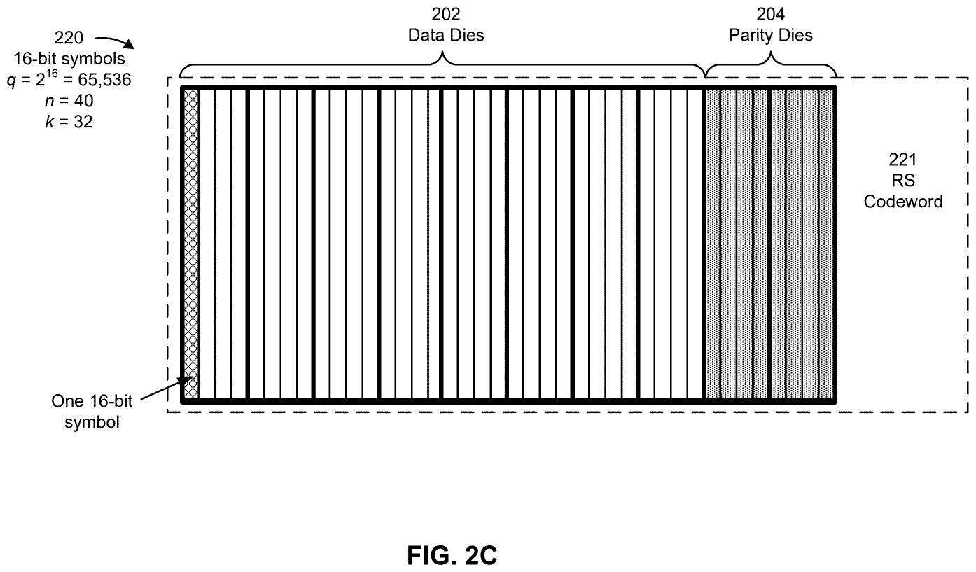

FIGS. 2A-2C are diagrams of examples associated with error correction codes. The operations described in connection with FIGS. 2A-2C may be performed by the memory system 110 and/or one or more components of the memory system 110, such as the memory system controller 115, one or more memory devices 120, one or more local controllers 125, and/or one or more ECC engines associated with the memory system 110 and/or one more memory devices 120.

As shown in FIG. 2A, an ECC may be used in connection with a memory stripe 200 (sometimes referred to as a data block, a data frame, and/or a similar term), which may correspond to the volatile memory arrays 135 described above in connection with FIG. 1. In some examples, the memory stripe 200 may be associated with a memory channel (e.g., a data pathway between memory and other components of a memory device, such as a memory controller and/or a processor), with a “width” of the memory channel (e.g., measured in bits) referring to a quantity of bits that may be transferred in one operation and/or one memory cycle. For example, as described in more detail below, in some examples the memory stripe 200 may be associated with a 40-bit channel, and thus a memory device associated with the memory stripe 200 may be referred to as a 40-bit memory device. For example, the memory device may be a double data rate 5 (DDR5) 40-bit memory device, or a similar device.

The memory stripe 200 may be associated with multiple dies of memory used to store data bits and/or parity bits. Put another way, in some examples multiple data bits and/or parity bits may be striped across multiple dies associated with the memory stripe 200. For example, the memory stripe 200 shown in FIG. 2A is associated with ten dies (e.g., ten DRAM dies), indexed as Die 0 through Die 9, with Dies 0-7 used to store data bits (and thus referred to as data dies, as indicated by reference number 202) and with Dies 8-9 used to store parity bits for error correction purposes (and thus referred to as parity dies, as indicated by reference number 204). As indicated by reference number 206, each die may be associated with sixteen bit lines (BLs) and/or, as indicated by reference number 208, each die may be configured in a “by four” (×4) configuration, such that each die includes four input/output pins (sometimes referred to as DQ pins). In this regard, each die may be capable of storing 64 bits (e.g., 8 bytes). In some examples, the memory stripe may be associated with 64 bytes of data (corresponding to the eight data dies indicated by reference number 202, each capable of storing 8 bytes) and 16 bytes of parity information (corresponding to the two parity dies indicated by reference number 204, each capable of storing 8 bytes). Put another way, the data dies of the memory stripe 200 may collectively store 512 data bits and/or the parity dies of the memory stripe 200 may collectively store 128 parity bits, with each of the 128 parity bits being a function of the 512 data bits. In this way, the 16 BL access to 64 bytes of data may include ten dies in ×4 mode, with eight dies providing the 64 bytes of data (e.g., 8 bytes per die) and with two dies providing the 16 bytes of redundancy (e.g., 8 bytes per die) for error correction purposes.

Moreover, as indicated by reference number 210, the memory stripe 200 may be associated with a 40-bit channel, of which 32 bits may be associated with data bits (as indicated by reference number 212) and 8 bits may be associated with parity bits (as indicated by reference number 214). In some examples, a memory system (e.g., memory system 110) may be organized into channels and/or ranks. For example, a memory system may include four ranks and/or 4×40-bit channels. In that regard, the memory stripe 200 shown in FIG. 2A may be associated with data provided by an access in a certain rank of a certain channel.

In some examples, the parity dies may store information that can be used in connection with an ECC to correct data, such as in an event in which an entire die fails (e.g., a chipkill protection). Put another way, an error correction system associated with the memory stripe 200 may be able to correct errors due to an entire die failure. For example, as indicated by reference number 216, in some events an entire die of a DRAM stack may fail (e.g., in the depicted example, Die 3 fails). In such cases, the parity bits stored in the parity dies may be encoded in such a way that the parity bits may be used to recover data that is stored on the failed die.

More particularly, FIGS. 2B and 2C show examples in which the parity dies are associated with RS codes and/or in which the memory stripe is associated with an RS chipkill protection scheme. As shown in FIG. 2B, and as indicated by reference number 218, a chipkill protection scheme may be obtained by using an RS code with 8-bit symbols. In such cases, a size of a symbol set (sometimes referred to as q) used in the RS coding scheme for the 40-bit memory stripe 200 described above in connection with FIG. 2A may be equal to 256 (e.g., 2⁸), a length of an RS codeword 219 (sometimes referred to as n and/or as a shortened codeword) may be 80 symbols, and a length of the data portion of the RS codeword (sometimes referred to as k) may be 64 symbols. In some examples, RS codes may be capable of correcting up to t symbols, with t being equal to

$$\frac{n - k}{2} .$$

Thus, for the 8-bit symbol example shown in FIG. 2B, the RS code may be capable of correcting up to

$$\frac{80 - 64}{2} = 8 symbols ( e . g . , 8 bytes ) ,$$

which is equivalent to an amount of data stored on one die of the memory stripe 200. In this regard, the 8-bit RS code may be used to provide chipkill protection in an event in which an entire die of the memory stripe fails.

Similarly, as shown in FIG. 2C, and as indicated by reference number 220, a chipkill protection scheme may be alternatively obtained by using an RS code with 16-bit symbols. In such cases, a size of a symbol set (e.g., q) used in the RS coding scheme for the 40-bit memory stripe 200 described above in connection with FIG. 2A may be equal to 65,536 (e.g., 2¹⁶), a length of the RS codeword 221 (e.g., n) may be 40 symbols, and a length of the data portion of the RS codeword (e.g., k) may be 32 symbols. Thus, the 16-bit symbol example may be capable of correcting up to 4 symbols

$$( e . g . , t = \frac{n - k}{2} = \frac{40 - 32}{2} = 4 symbols , or 8 bytes ) ,$$

which is equivalent to an amount of data stored on one die. In this regard, the 16-bit RS code may also be used to provide chipkill protection in an event in which an entire die of the memory stripe fails.

In this way, certain ECC procedures (e.g., ECC procedures implementing RS codes, such as the procedures described above in connection with FIGS. 2A-2C) are effective only if a single data storage element (e.g., one data die) fails and/or contains errors. This is because, for the 40-bit memory example described above, the parity bits stored on the parity dies may be capable of correcting only up to 8 bytes of data, which is equivalent to an amount of data stored on one die of the memory stripe 200. Accordingly, such ECC procedures may become ineffective if more than one data storage element of a memory stripe includes errors and/or fails (e.g., when two or more data dies associated with a memory stripe fail). Put another way, if a first chipkill event occurs in a memory system and/or in connection with the memory stripe 200, the RS code may be capable of correcting the error and/or retrieving the lost data. However, if a second chipkill event occurs in a memory system and/or in connection with the memory stripe 200, the RS code may not be capable of correcting the error and/or retrieving the lost data, resulting in an uncorrectable error. This may result in unreliable memory systems, unrecoverable host data, read/write errors, and high power, computing, and storage consumption for moving host data, rewriting host data, and/or recovering host data.

Some implementations described herein enable DDDC for certain memory systems, such as memory systems employing RS-based error correction schemes. In some implementations, a memory system may associate multiple memory stripes (e.g., two memory stripes) with each other, with each memory stripe including respective data storage elements (e.g., data dies) and respective error correction elements (e.g., parity dies). In some implementations, a memory controller, an encoder/decoder component of a memory system, and/or another component of a memory system may be capable of encoding and/or decoding an enlarged codeword after a first die failure, such as for a purpose of correcting errors associated with a second or subsequent die failure. For example, in some implementations, a memory system may associate two memory stripes with one another and/or pair original RS codewords. An original (e.g., un-enlarged) RS codeword may be used to correct a first die failure, such as by implementing an error correction procedure similar to those described above in connection with FIGS. 2A-2C. Moreover, following a first die failure, recovered data may be written to an error correction element (e.g., a parity die) of a first memory stripe, and the error correction elements of a second memory stripe may be used to store error correction bits for an enlarged codeword associated with both the first memory stripe and the second memory stripe. In this way, if another data storage element (e.g., a data die) of the first memory stripe and/or the second memory stripe fails, the memory system may recover the lost data using the error correction bits stored in the error correction elements of the second memory stripe, thereby enabling DDDC at the memory system. This may result in increased reliability of the memory system, reduced data loss and/or read/write errors, and reduced power, computing, and storage consumption otherwise required to move host data, rewrite host data, and/or recover host data.

As indicated above, FIGS. 2A-2C are provided as examples. Other examples may differ from what is described with regard to FIGS. 2A-2C.

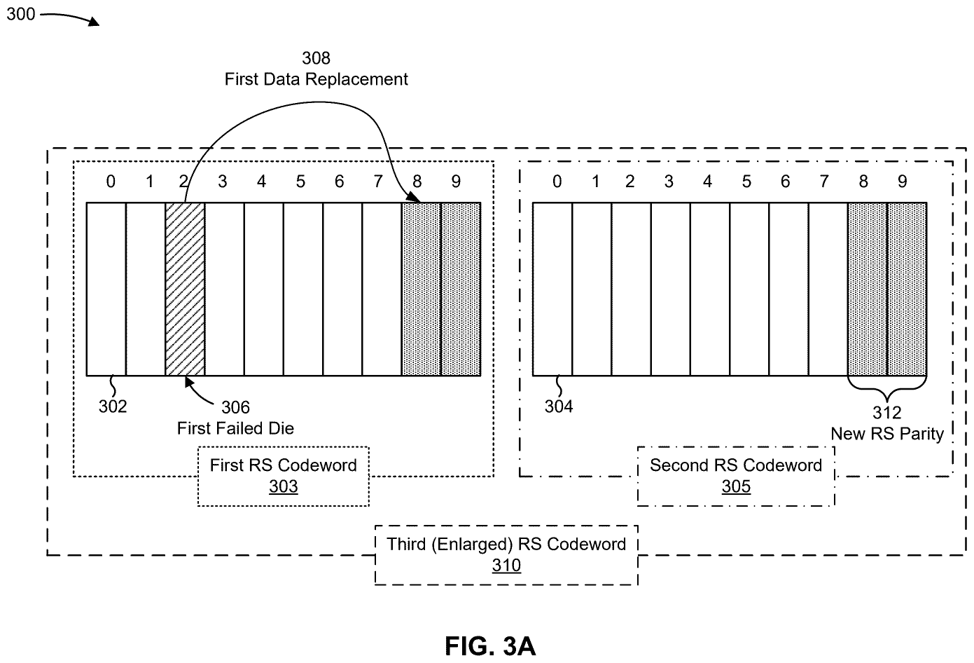

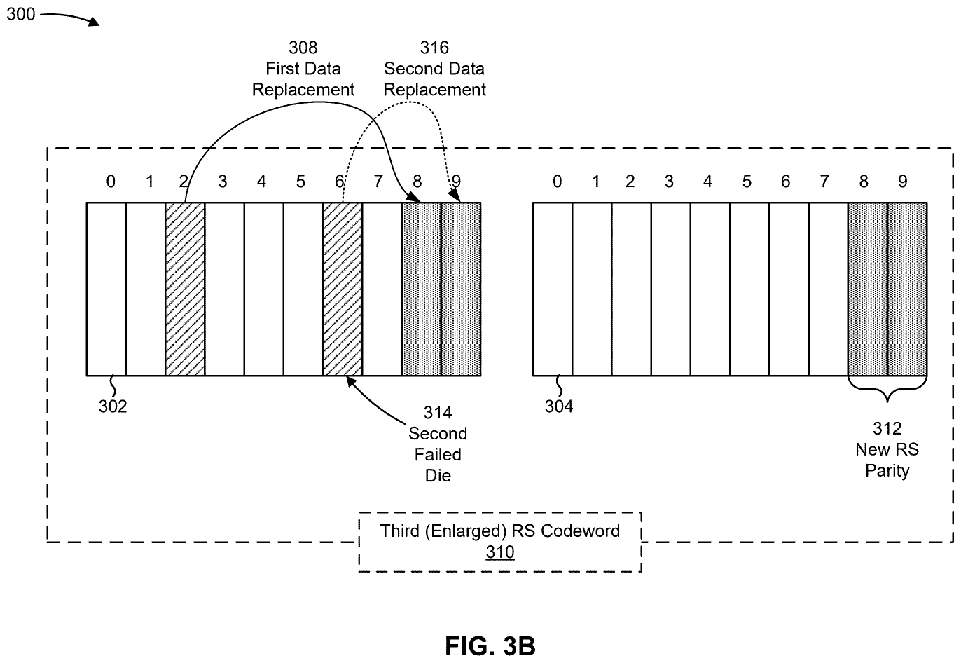

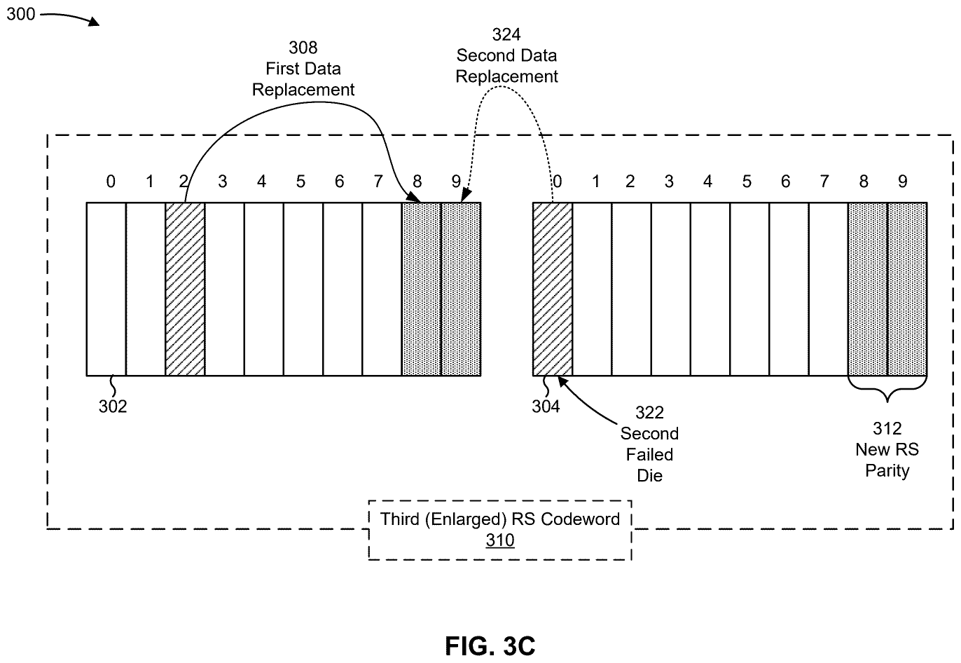

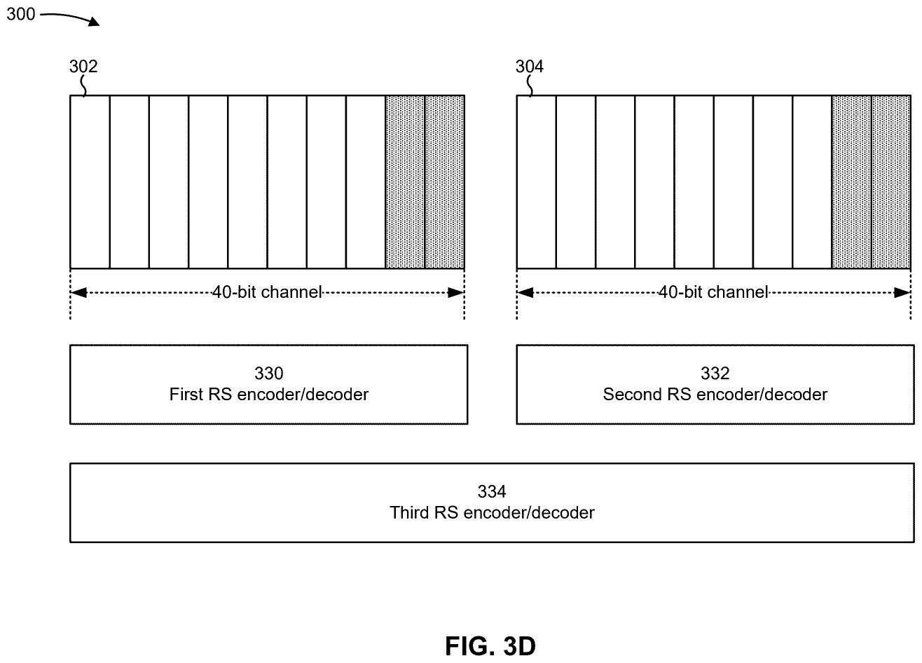

FIGS. 3A-3D are diagrams of an example 300 of DDDC in memory devices using enlarged RS codewords. The operations described in connection with FIGS. 3A-3D may be performed by the memory system 110 and/or one or more components of the memory system 110, such as the memory system controller 115, one or more memory devices 120, one or more local controllers 125, and/or one or more encoder/decoder components of the memory system 110 (which are described in more detail below in connection with FIG. 3D).

In some implementations, an ECC scheme (e.g., an ECC scheme associated with DDDC) may involve associating multiple memory stripes (e.g., multiple ones of the memory stripe 200 and/or similar memory stripes) with one another. For example, as shown in example 300, a memory controller, an encoder/decoder component of a memory system, and/or a similar component of a memory system may associate a first memory stripe 302 with a second memory stripe 304. In some implementations, each memory stripe 302, 304 may be associated with multiple data storage elements (e.g., data dates) and/or multiple error correction elements (e.g., parity dies), in a similar manner as described above in connection with the memory stripe 200. For example, each memory stripe 302, 304 may be associated with eight data storage components and/or data dies (e.g., the dies indexed 0-7 in the example 300) and/or two error correction components and/or parity dies (e.g., the dies indexed 8-9 in the example 300).

In some implementations, the memory controller, the encoder/decoder component of the memory system, and/or a similar component of a memory system may store an indication of an association between the first memory stripe 302 and the second memory stripe 304, such as within a dynamic storage component associated with the memory system (e.g., an SRAM component and/or a similar dynamic storage component). In this regard, when a host device (e.g., host system 105) accesses one of the memory stripes 302, 304, the memory controller, the encoder/decoder component of the memory system, and/or a similar component of a memory system may access a codeword associated with paired memory stripes (e.g., the first memory stripe 302 and the second memory stripe 304) to retrieve data requested by the host, which is described in more detail below.

In some implementations, each memory stripe 302, 304 may be associated with an ECC scheme, such as an RS-based ECC scheme (e.g., the 8-bit RS-based ECC scheme described above in connection with FIG. 2B or the 16-bit RS-based ECC scheme described above in connection with FIG. 2C, among other examples). In that regard, an RS codeword associated with each memory stripe may include data bits stored at the data storage elements (e.g., dies 0-7) of the corresponding memory stripe and/or error correction bits stored at the error correction elements (e.g., dies 8-9) of the corresponding memory stripe. For example, a first RS codeword 303 may be associated with the first memory stripe 302, which may include data bits stored at dies 0-7 of the first memory stripe 302 and/or error correction bits (e.g., parity bits) stored at dies 8-9 of the first memory stripe 302. Similarly, a second RS codeword 305 may be associated with the second memory stripe 304, which may include data bits stored at dies 0-7 of the second memory stripe 304 and/or error correction bits (e.g., parity bits) stored at dies 8-9 of the second memory stripe 304.

In this regard, when data is retrieved in response to a read command received from a host device and/or for a similar purpose, any errors detected in the first RS codeword 303 may be corrected using the parity information (e.g., error correction bits) included in the first RS codeword 303, and/or any errors detected in the second RS codeword 305 may be corrected using the parity information (e.g., error correction bits) included in the second RS codeword 305, in a similar manner as described above in connection with FIGS. 2A-2C. For example, as shown in FIG. 3A, and as indicated by reference number 306, a die associated with the first memory stripe 302 may fail, causing an encoder/decoder component to detect an error in the first RS codeword 303 during a read operation and/or a similar memory operation. Put another way, the encoder/decoder component may receive the first RS codeword 303 associated with the first memory stripe 302 (e.g., in response to receiving a read command from a host device associated with data stored at the first memory stripe 302), the encoder/decoder component may identify a first error in the first set of data bits using the first RS codeword 303 (e.g., may detect a cluster of errors associated with die 2, indicating that die 2 has failed), and/or may correct the first error using the first RS codeword 303, in a similar manner as described above in connection with FIGS. 2A-2C.

In some implementations, the memory system may store the corrected and/or recovered data using one of the error correction elements (e.g., one of the parity dies) of one of the paired memory stripes 302, 304, such as for a purpose of further error correction at the paired memory stripes (sometimes referred to herein as DDDC, indicative that errors from two or more failed dies may be corrected). More particularly, as indicated by reference number 308, the memory controller, the encoder/decoder component, and/or a similar component of the memory system may store the recovered and/or corrected data (e.g., the data associated with the failed die that was recovered using the parity bits of the first RS codeword 303) at a parity die (e.g., die 8) of the first memory stripe 302. Put another way, the memory controller, the encoder/decoder component, and/or a similar component of the memory system may replace parity information stored at a first error correction element associated with the first memory stripe 302 (e.g., die 8) with a first set of data associated with the error detected using the first RS codeword 303 (e.g., the error caused by the failed die, die 2).

By replacing parity information stored at an error correction element (e.g., die 8 of the first memory stripe 302) with the data of the failed die (e.g., die 2), the memory system may be capable of detecting and/or correcting subsequent errors associated with the first memory stripe 302 and/or the second memory stripe 304. More particularly, following the data replacement described above in connection with reference number 308, an encoder/decoder component and/or a similar component of a memory system may store a third RS codeword 310, which may include an enlarged RS payload as compared to the first RS codeword 303 and/or the second RS codeword 305 and/or that spans the paired memory stripes 302, 304. More particularly, as shown in FIG. 3A, the third RS codeword 310 may be associated with both the first memory stripe 302 and the second memory stripe 304, such that an RS payload of the third RS codeword 310 includes the remaining (e.g., operable) data dies of the first memory stripe 302 (e.g., dies 0-1 and 3-7 in the example shown in FIG. 3A), at least one parity die of the first memory stripe 302 (e.g., the die used to store the data of the failed die, such as die 8 in the example shown in FIG. 3A), and the operable data dies of the second memory stripe 304 (e.g., dies 0-7). Moreover, the third RS codeword 310 may be associated with two parity dies (e.g., dies 8-9 of the second memory stripe 304), which may store parity information for error correction of the enlarged payload associated with the third RS codeword 310.

In this regard, the third RS codeword 310 may be used for subsequent error correction, such as in an event in which another die associated with either the first memory stripe 302 or the second memory stripe 304 fails. For example, as shown in FIG. 3B, an encoder/decoder component and/or a similar component of a memory system may receive the third RS codeword 310, which may include data bits associated with the remaining operable data dies of the first memory stripe 302 (e.g., dies 0-1 and 3-7), data bits associated with the parity die that is now being used to store the recovered data of the failed die 2 (e.g., die 8), and data bits associated with the data dies of the second memory stripe 304 (e.g., dies 0-7), collectively referred to herein as the enlarged RS payload. The third RS codeword 310 may also include the parity bits associated with enlarged RS payload (e.g., dies 0-1 and 3-8 of the first memory stripe 302 and dies 0-7 of the second memory stripe), which may be associated with the parity dies (e.g., dies 8-9) of the second memory stripe 304, as described above in connection with reference number 312. In this way, if a subsequent error occurs in the enlarged RS payload, the encoder/decoder component may identify and/or correct the error using the new parity information.

More particularly, and as indicated by reference number 314, another die associated with the first memory stripe 302 may fail, causing an encoder/decoder component and/or a similar component of a memory system to detect an error in the third RS codeword 310. Put another way, the encoder/decoder component may receive the third RS codeword 310 associated with the enlarged RS payload, the encoder/decoder component may identify a second error in the enlarged RS payload using the third RS codeword 310 (e.g., may detect a cluster of errors associated with die 6 of the first memory stripe 302, indicating that die 6 has failed), and/or may correct the second error using the third RS codeword 310.

In a similar manner as described above in connection with reference number 308, in some implementations, the memory system may store the corrected and/or recovered data from the second failed die (e.g., die 6 of the first memory stripe 302) using one of the error correction elements (e.g., one of the parity dies) of one of the paired memory stripes 302, 304, such as for a purpose of further error correction at the paired memory stripes (e.g., such as for a purpose of identifying and/or correcting a third error and/or a third failed die). More particularly, as indicated by reference number 316, the memory controller, the encoder/decoder component, and/or a similar component of the memory system may store the second recovered and/or corrected data (e.g., the data associated with the second failed die) at a parity die (e.g., die 9) of the first memory stripe 302. Put another way, the memory controller, the encoder/decoder component, and/or a similar component of the memory system may replace parity information stored at a second error correction element associated with the first memory stripe 302 (e.g., die 9) with a second set of data associated with the error detected using the third RS codeword 310 (e.g., the error caused by the failed die, die 6).

By replacing parity information stored at an error correction element (e.g., die 9 of the first memory stripe 302) with the data of the failed die (e.g., die 6), the memory system may be capable of detecting and/or correcting a subsequent error associated with the first memory stripe 302 and/or the second memory stripe 304. More particularly, following the data replacement described above in connection with reference number 316, an encoder/decoder component and/or a similar component of a memory system may store a fourth RS codeword, which may include an enlarged RS payload as compared to the first RS codeword 303 and/or the second RS codeword 305 and/or that spans the paired memory stripes 302, 304. For example, the fourth RS codeword may be associated with both the first memory stripe 302 and the second memory stripe 304, such that an RS payload of the third RS codeword 310 includes the remaining (e.g., operable) data dies of the first memory stripe 302 (e.g., dies 0-1, 3-5, and 7 in the example shown in FIG. 3B), at least one parity die of the first memory stripe 302 (e.g., the dies used to store the data of the failed dies, such as dies 8-9 in the example shown in FIG. 3B), and the operable data dies of the second memory stripe 304 (e.g., dies 0-7). Moreover, the fourth RS codeword may be associated with two parity dies (e.g., dies 8-9 of the second memory stripe 304), which may store parity information for error correction of the enlarged payload associated with the fourth RS codeword. In this way, an encoder/decoder component of the memory system and/or a similar component may detect and/or correct a subsequent error (e.g., a third failed die) using the fourth RS codeword.

Although the implementation described above in connection with FIG. 3B shows a second failed die on a same memory stripe as the first failed die (e.g., the first memory stripe 302), in some other implementations the third RS codeword 310 (e.g., the enlarged RS codeword) may be used for a purpose of identifying and/or correcting errors on the second memory stripe 304 (e.g., identifying and/or correcting errors due to a failed die in the second memory stripe 304). More particularly, as shown in FIG. 3C, and as indicated by reference number 322, following enlargement of the RS payload and/or the RS codeword, a die associated with the second memory stripe 304 (e.g., die 0) may fail, causing an encoder/decoder component and/or a similar component of a memory system to detect an error in the third RS codeword 310. Put another way, the encoder/decoder component may receive the third RS codeword 310 associated with the enlarged RS payload, the encoder/decoder component may identify a second error in the enlarged RS payload using the third RS codeword 310 (e.g., may detect a cluster of errors associated with die 0 of the second memory stripe 304, indicating that the die 0 has failed), and/or may correct the second error using the third RS codeword 310, in a similar manner as described above in connection with FIG. 3B.

Moreover, in a similar manner as described above in connection with reference number 316 of FIG. 3B, in some implementations, the memory system may store the corrected and/or recovered data from the second failed die (e.g., die 0 of the second memory stripe 304 in the example shown in FIG. 3C) using one of the error correction elements (e.g., one of the parity dies) of one of the paired memory stripes 302, 304, such as for a purpose of further error correction at the paired memory stripes (e.g., such as for a purpose of identifying and/or correcting a third error and/or a third failed die). More particularly, as indicated by reference number 324, the memory controller, the encoder/decoder component, and/or a similar component of the memory system may store the second recovered and/or corrected data (e.g., the data associated with the second failed die) at a parity die (e.g., die 9) of the first memory stripe 302. Put another way, the memory controller, the encoder/decoder component, and/or a similar component of the memory system may replace parity information stored at a second error correction element associated with the first memory stripe 302 (e.g., die 9) with a second set of data associated with the error detected using the third RS codeword 310 (e.g., the error caused by the failed die, die 0 of the second memory stripe 304). By replacing parity information stored at an error correction element (e.g., die 9 of the first memory stripe 302) with the data of the failed die (e.g., die 0 of the second memory stripe 304), the memory system may be capable of detecting and/or correcting a subsequent error associated with the first memory stripe 302 and/or the second memory stripe 304 (e.g., using a fourth RS codeword that would include an RS payload of dies 0-1 and 3-9 of the first memory stripe 302 and dies 1-7 of the second memory stripe 304, and that would include parity information stored at dies 8-9 of the second memory stripe 304), in a similar manner as described above in connection with FIG. 3B.

FIG. 3D shows example encoder/decoder components (sometimes referred to herein as encoder/decoder blocks) of a memory system (e.g., memory system 110) that may be used to identify and/or correct multiple data device errors associated with memory stripes, such as the paired memory stripes 302, 304 described above in connection with FIGS. 3A-3C. As described above, each memory stripe 302, 304 may be associated with a 40-bit channel and/or may be paired with another memory stripe (e.g., logically associated with another memory stripe, with an indication of the association stored in a dynamic storage structure (e.g., SRAM) of a memory system). Accordingly, before a first error is detected in the first memory stripe 302 or the second memory stripe 304 (e.g., before a first chipkill event occurs), each memory stripe 302, 304 may be associated with a separate encoder/decoder component and/or a separate RS codeword. For example, the first memory stripe 302 may be associated with a first RS encoder/decoder component 330, and/or the second memory stripe 304 may be associated with a second RS encoder/decoder component 332. In this way, the first RS encoder/decoder component 330 may be capable of identifying and/or correcting errors associated with the first memory stripe 302, such as by using the parity information stored in the first RS codeword 303, and/or the second RS encoder/decoder component 332 may be capable of identifying and/or correcting errors associated with the second memory stripe 304, such as by using the parity information stored in the second RS codeword 305.

Following a first error correction procedure (e.g., a correction associated with a first failed die in one of the first memory stripe 302 or the second memory stripe 304), the memory system may use an enlarged RS payload that includes data from both the first memory stripe 302 and the second memory stripe 304, and/or may use an enlarged RS codeword (e.g., the third RS codeword 310), such as for a purpose of correcting subsequent errors in the first memory stripe 302 and/or the second memory stripe 304, as described above in connection with FIGS. 3A-3C. In that regard, following correction of the first error (as described above in connection with reference number 306) and/or following the first data replacement (as described above in connection with reference number 308), the paired memory stripes 302, 304 may be associated with a third RS encoder/decoder component 334, which may be an encoder/decoder component capable of encoding and/or decoding enlarged RS codewords (e.g., the third RS codeword 310) and/or handling enlarged RS payloads. For example, the third RS encoder/decoder component 334 may be capable of identifying and correcting second failed dies, third failed dies, or the like, as described above in connection with FIGS. 3B-3C.

In this regard, after a first chipkill event, access to the affected stripes (e.g., the first memory stripe 302 and the second memory stripe 304 in the example 300) may be impacted by a performance degradation, because the memory system (e.g., the third RS encoder/decoder component 334 of the memory system) may need to access two 40-bit channels at a time, as shown in FIG. 3D. In this way, the increased reliability benefits of the implementations described herein may come at a cost of performance degradation. Moreover, although the first RS encoder/decoder component 330, the second RS encoder/decoder component, and the third RS encoder/decoder component 334 are shown as separate components for ease of description, in some other implementations the RS encoder/decoder components may share certain components and/or logic. For example, in some implementations, the third RS encoder/decoder component 334 (e.g., the encoder/decoder component capable of encoding and/or decoding an enlarged RS codeword) may share logic with the first RS encoder/decoder component 330 and/or the second RS encoder/decoder component 332.

As indicated above, FIGS. 3A-3D are provided as an example. Other examples may differ from what is described with regard to FIGS. 3A-3D.

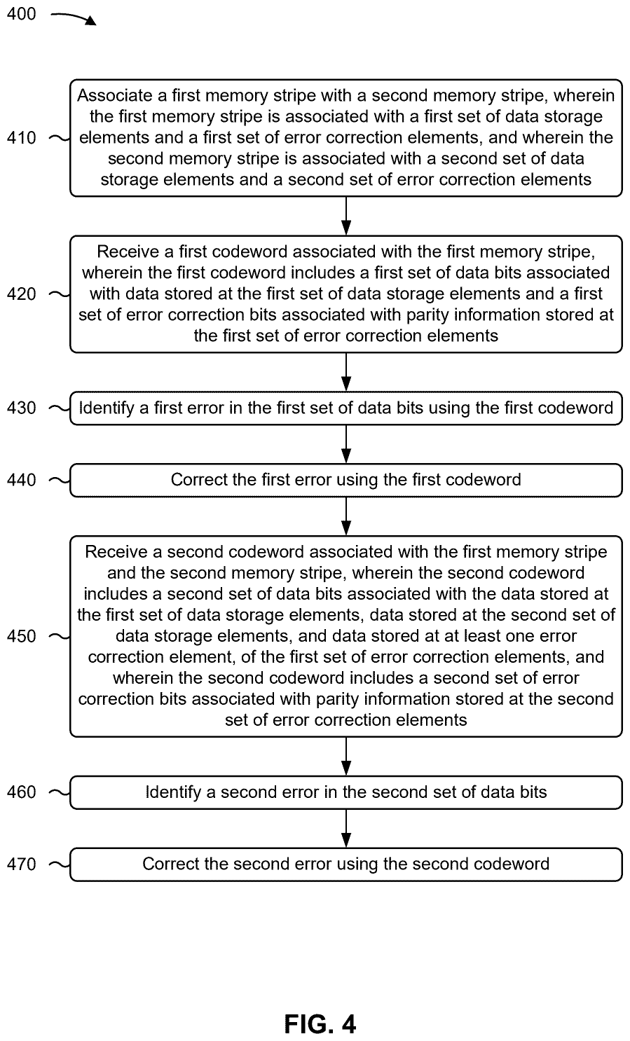

FIG. 4 is a flowchart of an example method 400 associated with double device data correction in memory devices using enlarged RS codewords. In some implementations, a memory system (e.g., the memory system 110) may perform or may be configured to perform the method 400. In some implementations, another device or a group of devices separate from or including the memory system 110 (e.g., a memory device 120) may perform or may be configured to perform the method 400. Additionally, or alternatively, one or more components of the memory system 110 and/or the memory device 120 (e.g., the memory system controller 115, the local controller 125, the first RS encoder/decoder component 330, the second RS encoder/decoder component 332, and/or the third RS encoder/decoder component 334) may perform or may be configured to perform the method 400. Thus, means for performing the method 400 may include the memory system and/or the memory device and/or one or more components of the memory system and/or the memory device. Additionally, or alternatively, a non-transitory computer-readable medium may store one or more instructions that, when executed by the memory system and/or memory device (e.g., the memory system controller 115 of the memory system 110 and/or the local controller 125 of the memory device 120), cause the memory system and/or the memory device to perform the method 400.

As shown in FIG. 4, the method 400 may include associating a first memory stripe (e.g., first memory stripe 302) with a second memory stripe (e.g., second memory stripe), wherein the first memory stripe is associated with a first set of data storage elements (e.g., data dies, dies 0-7) and a first set of error correction elements (e.g., parity dies, dies 8-9), and wherein the second memory stripe is associated with a second set of data storage elements (e.g., data dies, dies 0-7) and a second set of error correction elements (e.g., parity dies, dies 8-9) (block 410). As further shown in FIG. 4, the method 400 may include receiving a first codeword (e.g., first RS codeword 303) associated with the first memory stripe, wherein the first codeword includes a first set of data bits associated with data stored at the first set of data storage elements and a first set of error correction bits associated with parity information stored at the first set of error correction elements (block 420). As further shown in FIG. 4, the method 400 may include identifying a first error (e.g., the first failed die described above in connection with reference number 306) in the first set of data bits using the first codeword (block 430). As further shown in FIG. 4, the method 400 may include correcting the first error using the first codeword (block 440). As further shown in FIG. 4, the method 400 may include receiving a second codeword associated with the first memory stripe and the second memory stripe (e.g., third RS codeword 310), wherein the second codeword includes a second set of data bits associated with the data stored at the first set of data storage elements, data stored at the second set of data storage elements, and data stored at at least one error correction element, of the first set of error correction elements (e.g., the replaced data stored at die 8 of the first memory stripe 302, as described above in connection with reference number 308), and wherein the second codeword includes a second set of error correction bits associated with parity information stored at the second set of error correction elements (e.g., the new parity information stored at dies 8-9 of the second memory stripe 304, as described above in connection with reference number 312) (block 450). As further shown in FIG. 4, the method 400 may include identifying a second error in the second set of data bits (e.g., the second failed die, as described above in connection with reference numbers 314 and 322) (block 460). As further shown in FIG. 4, the method 400 may include correcting the second error using the second codeword (block 470).

The method 400 may include additional aspects, such as any single aspect or any combination of aspects described below and/or described in connection with one or more other methods or operations described elsewhere herein.

In a first aspect, the first codeword is a first RS codeword associated with a first RS payload, wherein the second codeword is associated with a second RS codeword associated with a second RS payload, and wherein the first RS payload is larger than the second RS payload (e.g., the second RS payload is the enlarged RS payload described above in connection with FIGS. 3A-3D).

In a second aspect, alone or in combination with the first aspect, the method 400 includes replacing, by the memory device, parity information stored at a first error correction element, of the first set of error correction elements, with a first set of data associated with the first error.

In a third aspect, alone or in combination with one or more of the first and second aspects, the method 400 includes replacing, by the memory device, parity information stored at a second error correction element, of the first set of error correction elements (e.g., die 9 of the first memory stripe 302, as described above in connection with reference numbers 316 and 324), with a second set of data associated with the second error.

In a fourth aspect, alone or in combination with one or more of the first through third aspects, the method 400 includes determining, by the memory device, the parity information stored at the second set of error correction elements based on replacing the parity information stored at the first error correction element with the first set of data.

In a fifth aspect, alone or in combination with one or more of the first through fourth aspects, the method 400 includes receiving, by the memory device, a third codeword associated with the first memory stripe and the second memory stripe (e.g., the fourth RS codeword described above in connection with FIGS. 3B and 3C), wherein the third codeword includes a third set of data bits associated with the data stored at the first set of data storage elements (e.g., the remaining operable data dies of the first memory stripe 302), the data stored at the second set of data storage elements (e.g., the remaining operable data dies of the second memory stripe 304), and data stored at the first set of error correction elements (e.g., dies 8-9 of the first memory stripe, following the second data replacement described above in connection with reference numbers 316 and 324), and wherein the third codeword includes a third set of error correction bits associated with parity information stored at the second set of error correction elements (e.g., dies 8-9 of the second memory stripe 304), identifying, by the memory device, a third error in the third set of data bits, and correcting, by the memory device, the third error using the third codeword.

In a sixth aspect, alone or in combination with one or more of the first through fifth aspects, the method 400 includes storing, by the memory device and in a dynamic storage component (e.g., SRAM), an indication of an association between the first memory stripe and the second memory stripe.

Although FIG. 4 shows example blocks of a method 400, in some implementations, the method 400 may include additional blocks, fewer blocks, different blocks, or differently arranged blocks than those depicted in FIG. 4. Additionally, or alternatively, two or more of the blocks of the method 400 may be performed in parallel. The method 400 is an example of one method that may be performed by one or more devices described herein. These one or more devices may perform or may be configured to perform one or more other methods based on operations described herein.

In some implementations, a memory device includes one or more components configured to: associate a first memory stripe with a second memory stripe, wherein the first memory stripe is associated with a first set of data storage elements and a first set of error correction elements, and wherein the second memory stripe is associated with a second set of data storage elements and a second set of error correction elements; receive a first codeword associated with the first memory stripe, wherein the first codeword includes a first set of data bits associated with data stored at the first set of data storage elements and a first set of error correction bits associated with parity information stored at the first set of error correction elements; identify a first error in the first set of data bits using the first codeword; correct the first error using the first codeword; receive a second codeword associated with the first memory stripe and the second memory stripe, wherein the second codeword includes a second set of data bits associated with the data stored at the first set of data storage elements, data stored at the second set of data storage elements, and data stored at at least one error correction element, of the first set of error correction elements, and wherein the second codeword includes a second set of error correction bits associated with parity information stored at the second set of error correction elements; identify a second error in the second set of data bits; and correct the second error using the second codeword.

In some implementations, a method includes associating, by a memory device, a first memory stripe with a second memory stripe, wherein the first memory stripe is associated with a first set of data storage elements and a first set of error correction elements, and wherein the second memory stripe is associated with a second set of data storage elements and a second set of error correction elements; receiving, by the memory device, a first codeword associated with the first memory stripe, wherein the first codeword includes a first set of data bits associated with data stored at the first set of data storage elements and a first set of error correction bits associated with parity information stored at the first set of error correction elements; identifying, by the memory device, a first error in the first set of data bits using the first codeword; correcting, by the memory device, the first error using the first codeword; receiving, by the memory device, a second codeword associated with the first memory stripe and the second memory stripe, wherein the second codeword includes a second set of data bits associated with the data stored at the first set of data storage elements, data stored at the second set of data storage elements, and data stored at at least one error correction element, of the first set of error correction elements, and wherein the second codeword includes a second set of error correction bits associated with parity information stored at the second set of error correction elements; identifying, by the memory device, a second error in the second set of data bits; and correcting, by the memory device, the second error using the second codeword.

In some implementations, a memory system includes a memory controller; and multiple encoder/decoder components associated with the memory controller, wherein the memory system is configured to: associate, by the memory controller, a first memory stripe with a second memory stripe, wherein the first memory stripe is associated with a first set of data storage elements and a first set of error correction elements, and wherein the second memory stripe is associated with a second set of data storage elements and a second set of error correction elements; receive, by a first encoder/decoder component, of the multiple encoder/decoder components, a first codeword associated with the first memory stripe, wherein the first codeword includes a first set of data bits associated with data stored at the first set of data storage elements and a first set of error correction bits associated with parity information stored at the first set of error correction elements; identify, by the first encoder/decoder component, a first error in the first set of data bits using the first codeword; correct, by the first encoder/decoder component, the first error using the first codeword; receive, by a second encoder/decoder component, a second codeword associated with the first memory stripe and the second memory stripe, wherein the second codeword includes a second set of data bits associated with the data stored at the first set of data storage elements, data stored at the second set of data storage elements, and data stored at at least one error correction element, of the first set of error correction elements, and wherein the second codeword includes a second set of error correction bits associated with parity information stored at the second set of error correction elements; identify, by the second encoder/decoder component, a second error in the second set of data bits; and correct, by the second encoder/decoder component, the second error using the second codeword.

The foregoing disclosure provides illustration and description but is not intended to be exhaustive or to limit the implementations to the precise forms disclosed. Modifications and variations may be made in light of the above disclosure or may be acquired from practice of the implementations described herein.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A memory device, comprising:
one or more components configured to:
associate a first memory stripe with a second memory stripe,
wherein the first memory stripe is associated with a first set of data storage elements and a first set of error correction elements, and
wherein the second memory stripe is associated with a second set of data storage elements and a second set of error correction elements;
receive a first codeword associated with the first memory stripe,
wherein the first codeword includes a first set of data bits associated with data stored at the first set of data storage elements and a first set of error correction bits associated with parity information stored at the first set of error correction elements;
identify a first error in the first set of data bits using the first codeword;
correct the first error using the first codeword;
receive a second codeword associated with the first memory stripe and the second memory stripe,
wherein the second codeword includes a second set of data bits associated with the data stored at the first set of data storage elements, data stored at the second set of data storage elements, and data stored at at least one error correction element, of the first set of error correction elements, and
wherein the second codeword includes a second set of error correction bits associated with parity information stored at the second set of error correction elements;
identify a second error in the second set of data bits; and
correct the second error using the second codeword.

2. The memory device of claim 1, wherein the first codeword is a first Reed-Solomon (RS) codeword associated with a first RS payload,
wherein the second codeword is associated with a second RS codeword associated with a second RS payload, and
wherein the first RS payload is larger than the second RS payload.

3. The memory device of claim 1, wherein the one or more components are further configured to replace parity information stored at a first error correction element, of the first set of error correction elements, with a first set of data associated with the first error.

4. The memory device of claim 3, wherein the one or more components are further configured to replace parity information stored at a second error correction element, of the first set of error correction elements, with a second set of data associated with the second error.

5. The memory device of claim 3, wherein the one or more components are further configured to determine the parity information stored at the second set of error correction elements based on replacing the parity information stored at the first error correction element with the first set of data.

6. The memory device of claim 1, wherein the one or more components are further configured to:
receive a third codeword associated with the first memory stripe and the second memory stripe,
wherein the third codeword includes a third set of data bits associated with the data stored at the first set of data storage elements, the data stored at the second set of data storage elements, and data stored at the first set of error correction elements, and
wherein the third codeword includes a third set of error correction bits associated with parity information stored at the second set of error correction elements;
identify a third error in the third set of data bits; and
correct the third error using the third codeword.

7. The memory device of claim 1, wherein the one or more components are further configured to store, in a dynamic storage component, an indication of an association between the first memory stripe and the second memory stripe.

8. A method, comprising:
associating, by a memory device, a first memory stripe with a second memory stripe,
wherein the first memory stripe is associated with a first set of data storage elements and a first set of error correction elements, and
wherein the second memory stripe is associated with a second set of data storage elements and a second set of error correction elements;
receiving, by the memory device, a first codeword associated with the first memory stripe,
wherein the first codeword includes a first set of data bits associated with data stored at the first set of data storage elements and a first set of error correction bits associated with parity information stored at the first set of error correction elements;
identifying, by the memory device, a first error in the first set of data bits using the first codeword;
correcting, by the memory device, the first error using the first codeword;
receiving, by the memory device, a second codeword associated with the first memory stripe and the second memory stripe,
wherein the second codeword includes a second set of data bits associated with the data stored at the first set of data storage elements, data stored at the second set of data storage elements, and data stored at at least one error correction element, of the first set of error correction elements, and
wherein the second codeword includes a second set of error correction bits associated with parity information stored at the second set of error correction elements;
identifying, by the memory device, a second error in the second set of data bits; and
correcting, by the memory device, the second error using the second codeword.

9. The method of claim 8, wherein the first codeword is a first Reed-Solomon (RS) codeword associated with a first RS payload,
wherein the second codeword is associated with a second RS codeword associated with a second RS payload, and
wherein the first RS payload is larger than the second RS payload.

10. The method of claim 8, further comprising replacing, by the memory device, parity information stored at a first error correction element, of the first set of error correction elements, with a first set of data associated with the first error.

11. The method of claim 10, further comprising replacing, by the memory device, parity information stored at a second error correction element, of the first set of error correction elements, with a second set of data associated with the second error.

12. The method of claim 10, further comprising determining, by the memory device, the parity information stored at the second set of error correction elements based on replacing the parity information stored at the first error correction element with the first set of data.

13. The method of claim 8, further comprising:
receiving, by the memory device, a third codeword associated with the first memory stripe and the second memory stripe,
wherein the third codeword includes a third set of data bits associated with the data stored at the first set of data storage elements, the data stored at the second set of data storage elements, and data stored at the first set of error correction elements, and
wherein the third codeword includes a third set of error correction bits associated with parity information stored at the second set of error correction elements;
identifying, by the memory device, a third error in the third set of data bits; and
correcting, by the memory device, the third error using the third codeword.

14. The method of claim 8, further comprising storing, by the memory device and in a dynamic storage component, an indication of an association between the first memory stripe and the second memory stripe.

15. A memory system, comprising:
a memory controller; and
multiple encoder/decoder components associated with the memory controller,
wherein the memory system is configured to:
associate, by the memory controller, a first memory stripe with a second memory stripe,
wherein the first memory stripe is associated with a first set of data storage elements and a first set of error correction elements, and
wherein the second memory stripe is associated with a second set of data storage elements and a second set of error correction elements;
receive, by a first encoder/decoder component, of the multiple encoder/decoder components, a first codeword associated with the first memory stripe,
wherein the first codeword includes a first set of data bits associated with data stored at the first set of data storage elements and a first set of error correction bits associated with parity information stored at the first set of error correction elements;
identify, by the first encoder/decoder component, a first error in the first set of data bits using the first codeword;
correct, by the first encoder/decoder component, the first error using the first codeword;
receive, by a second encoder/decoder component, a second codeword associated with the first memory stripe and the second memory stripe,
wherein the second codeword includes a second set of data bits associated with the data stored at the first set of data storage elements, data stored at the second set of data storage elements, and data stored at at least one error correction element, of the first set of error correction elements, and
wherein the second codeword includes a second set of error correction bits associated with parity information stored at the second set of error correction elements;
identify, by the second encoder/decoder component, a second error in the second set of data bits; and
correct, by the second encoder/decoder component, the second error using the second codeword.

16. The memory system of claim 15, wherein the first codeword is a first Reed-Solomon (RS) codeword associated with a first RS payload,
wherein the second codeword is associated with a second RS codeword associated with a second RS payload, and
wherein the first RS payload is larger than the second RS payload.

17. The memory system of claim 15, wherein the memory system is further configured to replace, by the first encoder/decoder component, parity information stored at a first error correction element, of the first set of error correction elements, with a first set of data associated with the first error.

18. The memory system of claim 17, wherein the memory system is further configured to replace, by the second encoder/decoder component, parity information stored at a second error correction element, of the first set of error correction elements, with a second set of data associated with the second error.

19. The memory system of claim 17, wherein the memory system is further configured to determine, by the second encoder/decoder component, the parity information stored at the second set of error correction elements based on replacing the parity information stored at the first error correction element with the first set of data.

20. The memory system of claim 15, wherein the memory system is further configured to:
receive, by the second encoder/decoder component, a third codeword associated with the first memory stripe and the second memory stripe,
wherein the third codeword includes a third set of data bits associated with the data stored at the first set of data storage elements, the data stored at the second set of data storage elements, and data stored at the first set of error correction elements, and
wherein the third codeword includes a third set of error correction bits associated with parity information stored at the second set of error correction elements;
identify, by the second encoder/decoder component, a third error in the third set of data bits; and
correct, by the second encoder/decoder component, the third error using the third codeword.
